(19) United States
(12) Patent Application Publication
(10) Pub. No.: US 2025/0387995 A1
(43) Pub. Date: Dec. 25, 2025

(54) 3D PRINTED CONSTRUCTION FOR HYBRID PANELS

(71) Applicant: Intel Corporation, Santa Clara, CA (US)

(72) Inventor: Ao WANG, Chandler, AZ (US)

(21) Appl. No.: 18/751,386

(22) Filed: Jun. 24, 2024

(51) Int. Cl. B32B 3/04; B32B 7/12; B32B 17/06; B32B 37/12; B32B 38/00; B32B 41/00

(52) U.S. Cl. CPC B32B 3/04; B32B 7/12; B32B 17/061; B32B 37/1284; B32B 41/00; B32B 2037/1253; B32B 2038/0076; B32B 2307/7375; B32B 2310/0831; B32B 2311/12; B32B 2315/08; B32B 2333/08

(57) ABSTRACT

According to the various aspects, a hybrid panel assembly includes a glass panel, a frame configured to surround the glass panel, and a layer manufactured binder disposed between and bonds the glass panel and the frame. In an aspect, the layer manufactured binder is made of a cured resin that is formed layer-by-layer and the frame is made of a copper clad laminate.

### BACKGROUND

For integrated circuit design and fabrication, the need to improve performance and lower costs are constant challenges. The continuing trend towards miniaturization, i.e., a reduction in the form factor for a printed circuit board with a semiconductor package and various other components, may lead to lower material costs, as well as improved performance with more compact designs. Further cost savings may potentially be realized by building dies on semiconductor panels rather than semiconductor wafers.

By using a rectangular panel as a substrate, panel-level fan-out technology offers the potential for lower production cost due to a higher area utilization ratio of the carrier and better economical manufacturing, especially for large packages. Presently, there are efforts to develop panel-level packaging technology that will follow a roadmap that will lead to increasingly larger panels, e.g., 610 mm by 650 mm panels and larger. However, there may be physical limits in panel-level packaging that may prevent the use of larger panels, such as warpage, and it has become clear that the manufacturing of these types of packages requires the use of a rigid core material, such as glass.

However, the brittle nature of glass may result in handling challenges during the course of a substrate flow process. While small chips and defects may not immediately degrade a glass core, the presence of edge chipping in the glass core caused by contact between a corner/edge of the glass core and a processing tool may lead to damage to the whole panel from stress that accumulates as the build-up layers with different coefficient of thermal expansion (CTE) are stacked on top of the glass core. The cracks initiated from small defects may propagate through the glass core resulting in “SeWaRe” (i.e., glass core splitting). Such glass core splitting may specifically arise during end-of-line singulation and other semiconductor processing steps. Accordingly, various methods for edge protection have been used to help glass core substrate panels avoid being damaged during the manufacturing process flow.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIGS. 1 and 1A show an exemplary representation of a hybrid panel according to an aspect of the present disclosure;

FIGS. 2A, 2B, and 2C show an exemplary representation of a layer manufactured binder formed in a bath solution according to an aspect of the present disclosure;

FIGS. 3, 4, and 5 show exemplary representation of layer manufactured binders for hybrid panels according to an aspect of the present disclosure; and

FIG. 6 shows a simplified flow diagram for an exemplary method according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

The conventional approach to bonding a frame and glass substrate panel is by molding or dry film lamination. The polymer film or polymer granules are placed in the trench/gap between the frame and glass panel and is followed by molding and lamination. The polymers are ‘squeezed’ into the high aspect ratio trench and, thereafter, the polymers are cured to fully crosslinked.

According to the present disclosure, a present hybrid panel may be constructed using stereolithography, i.e., 3D printing, to achieve precision control to produce a substantially void-free layer manufactured binder between a glass panel and a copper clad laminate (CCL) frame. The stereolithography process is able to bond the CCLframe and the glass panel without having excess cured polymer on the surface of the glass panel, i.e., only bonding at the sidewalls of the glass panel and, if needed, the area proximal thereto. In addition, the stereolithography process is able to precisely control the bonding patterns, i.e., the structure of the layer manufactured binder between the glass panel and the CCL frame, and use a wider choice of materials, e.g., polymers with low thermal stress properties.

In an aspect, the present method for assembling a hybrid panel provides for immersing a pre-cut glass panel and a pre-cut CCL frame in a bath with a UV-curable polymer solution. A pre-programmed curing pattern may be provided, by way of a controller, to control the movement of one or more UV-light sources to layer-by-layer form a layer manufactured binder for the hybrid panel. The targeted UV light may be used to form the layer manufactured binder for the hybrid panel having pre-designed bonding area shape and thickness. After the construction of the hybrid panel is complete, the hybrid panel is taken out of the bath and cleaned, e.g., the residue polymer solution is rinsed off.

The present disclosure is directed to a hybrid panel assembly including a glass panel, a copper clad laminate (CCL) configured as a CCL frame around the glass panel and forms a trench therebetween and a layer manufactured binder that is disposed in the trench between the glass panel and the CCL frame. In an aspect, the layer manufactured binder is made of a cured resin that is formed layer-by-layer to form an substantially void-free structure.

The present disclosure is also directed to a method that includes forming a glass panel having outer peripheral edges, forming a CCL frame having inner peripheral edges, providing a bath containing a solution comprising a curable polymer, positioning the CCL frame and the glass panel in the bath so that the outer peripheral edges of the glass panel are aligned with the inner peripheral edges of the CCL frame to form a trench between the CCL frame and the glass panel, and forming a layer manufactured binder in the trench to bond the CCL frame and the glass panel to form a hybrid panel assembly.

The present disclosure is directed to a hybrid panel assembly including a glass panel, a frame configured to surround the glass panel, and a layer manufactured binder disposed between and bonds the glass panel and the frame. In an aspect, the layer manufactured binder is made of a cured epoxy-based resin or acrylic-based resin that is formed layer-by-layer using a stereolithographic process, and the frame is made of a copper clad laminate.

The technical advantages of the present disclosure include, but are not limited to:
(i) providing a hybrid panel with a layer manufactured binder having precisely controlled dimensions;
(ii) providing a hybrid panel with a layer manufactured binder for trenches with narrow dimensions; and
(iii) providing a method for the construction of a layer manufactured binder for a hybrid panel that substantially eliminates voids between the glass panel and the CCL frame.

To more readily understand and put into practical effect the present hybrid panel assembly and methods, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

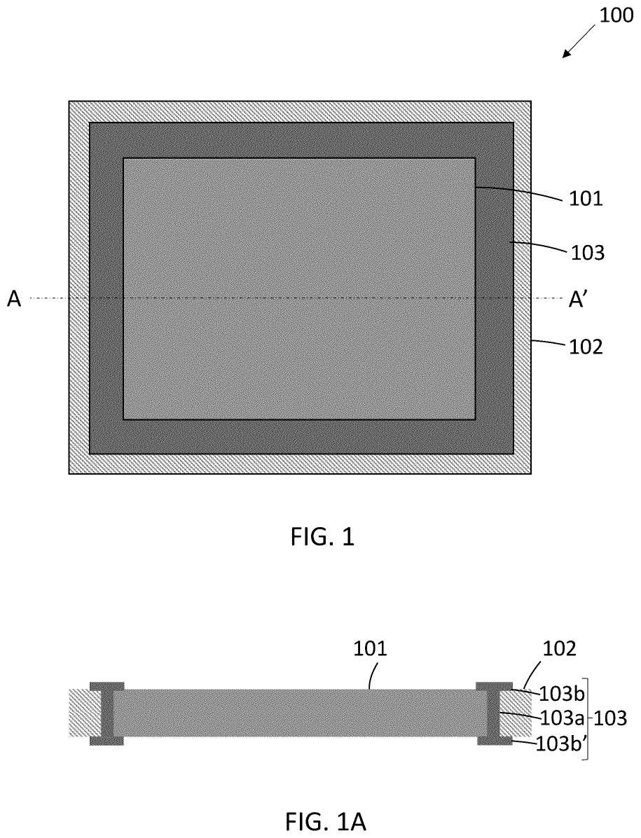

FIGS. 1 and 1A show an exemplary representation of a hybrid panel 100 according to an aspect of the present disclosure. The hybrid panel 100 is an assembly formed by a glass panel 101 and copper clad laminate (CCL) frame 102 that is bonded together by a layer manufactured binder 103. The CCL frame may be made from a commercially available CCL panel. The hybrid panel 100 provides a unitary structure that may be transported and placed in semiconductor processing tools for build-up process steps used to construct semiconductor packages.

In an aspect, the hybrid panel may have a glass panel that has a size (i.e., width and length) in the range of approximately 250×250 mm to 610×650 mm, and a thickness in the range of approximately 200 to 1800 μm. In another aspect, the hybrid panel assembly of the glass panel and the CCL frame have a size of approximately 510×515 mm, which may be suitable for most semiconductor packaging tool designs.

As shown in FIG. 1A, a cross-section view of the hybrid panel 100 is provided along section line A-A′. In this view, the layer manufactured binder 103 may have a first section 103a that is formed between the glass panel 101 and the CCL frame 102, and second sections 103b and 103b′ that are formed to bridge across the top and bottom surfaces of the glass panel 101 and the CCL frame 102 to provide further stability for the hybrid panel 100. In this aspect, the layer manufactured binder has a thickness that is greater than a thickness of the glass panel.

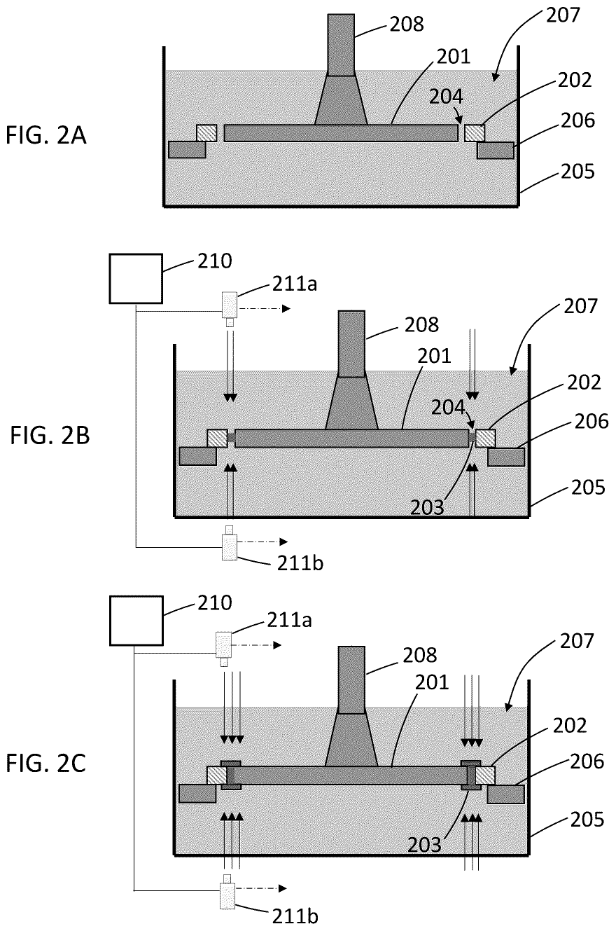

FIGS. 2A, 2B, and 2C show an exemplary representation of process steps for forming a layer manufactured binder in a bath solution according to an aspect of the present disclosure. As shown in FIG. 2A, a bath 205 may have a frame support 206 and may be filled with a curable polymer solution 207. The bath 205 may be provided in a module of a tool (not shown). The curable polymer solution 207 may include photocurable liquid resins, e.g., epoxy-based resin or acrylic-based resin, and filler materials, e.g., ceramics or metal particles, to strengthen the bonding. In this aspect, a CCL frame 202 may be disposed on the frame support 206 and a glass panel 201 may be positioned within the CCL frame 202. The glass panel 201 may be held by a positioning arm 208, which holds the glass panel 201 using vacuum suction. The glass panel 201 and the CCL frame 202 may be produced to have pre-cut sizes that, when positioned together, a small trench or gap 204 is formed. The trench 204 between the CCL frame and glass may have a high aspect ratio (e.g., greater than 10:1). The glass panel 201 may be aligned with the CCL frame using one or more alignment sensors (not shown).

As shown in FIGS. 2B and 2C, UV-lasers 211a and 211b may be provided to direct localized UV-curing of the polymer solution 207 in the bath 205 at the trench 204 to form the layer manufactured binder 203. The UV-lasers 211a and 211b may be coupled to a controller 210, which may have a pre-programmed pattern provided therein, that directs the UV-lasers to move along the trench 204 to form the layer manufactured binder 203 in a layer-by-layer method. The use of stereolithography may produce a printed layer manufactured binder structures using programmed UV laser shots, and the layer manufactured binder 203 will completely fill the trench 204 creating little or no voids, i.e., substantially void-free binder structures. In this aspect, the term “substantially” void-free may encompass binder structures having voids with volumes of less than 10 percent of the overall structure. The layer manufactured binder 203 is shown as being completed in FIG. 2C.

In an aspect, the polymer solution 207 may, for example, contain a photo-initiator having a composition of 20 gm—IGM Resin Omnirad 819 (phenyl bis(2,4,6-trimethyl benzyl) phosphine oxide, CAS 162881-26-7) or 4 gm—BASF TPO (diphenyl (2,4,6-trimethyl benzoyl) phosphine oxide, CAS 75980-60-8), 500 gm—1,6-Hexanediol diacrylate (HDDA) monomer diluent, and 500 gm—Dymax BT-970 (a polyurethane difunctional acrylate).

In a further aspect, the assembled hybrid panel may be removed from the bath and cleaned, e.g., using an isopropyl alcohol rinse or ultrasonic bath, to remove any residual polymer solution from the surfaces of the hybrid panel.

It should be understood that the present layer manufactured binder may be formed by other methods that are directed to 3-dimensional printed/manufacturing technology. In addition, the UV-curing method may be replaced with a thermal curing method to produce a layer manufactured binder for the present hybrid panel.

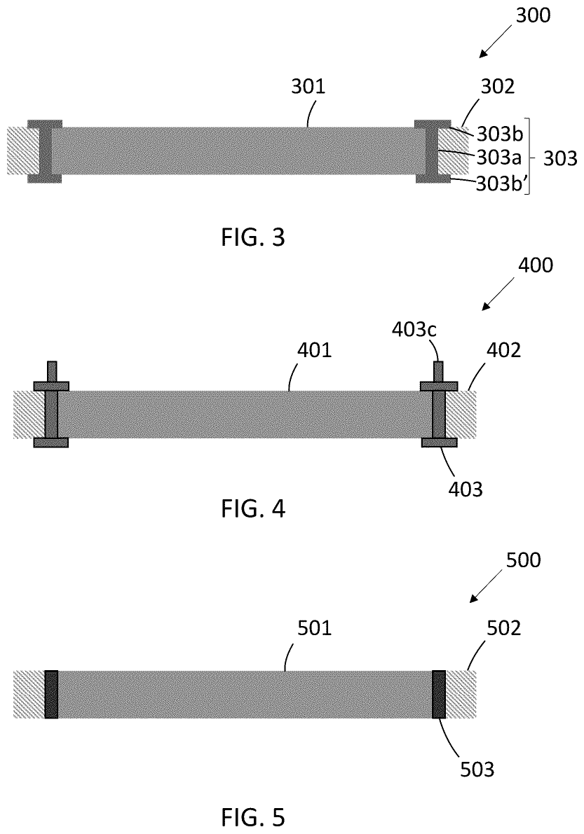

FIGS. 3, 4, and 5 show exemplary representation of layer manufactured binders for hybrid panels according to various aspects of the present disclosure.

In an aspect, the construction of a layer manufactured binder structure is performed by programmed UV-laser shots directed into a bath, with a focus area or target region being a trench or gap between a glass panel and a panel frame. A controller may be provided with a UV-laser “recipe” that determines the polymerization location, rate, and pattern. Accordingly, a present hybrid panel may be assembled that bonds a glass panel and the panel frame with solidified polymers only in the trench/gap and does not overflow to cover the glass surface in unintended areas.

As shown in FIG. 3, a hybrid panel 300 may have a layer manufactured binder 303 with a first section 303a that is a vertical section formed between the glass panel 301 and the CCL frame 302, and second sections 303b and 303b′ that are horizontal sections formed, respectively, to bridge across the top and bottom surfaces of the glass panel 301 and the CCL frame 302 to provide further stability for the hybrid panel 300. As shown in FIG. 4, a hybrid panel 400 may have a layer manufactured binder 403 that may have an additional feature 403c that is formed, for example, as an alignment marker for the hybrid panel 400. As shown in FIG. 5, a hybrid panel 500 may have a layer manufactured binder 503 may have upper and lower surfaces that are co-planar with the top and bottom surfaces, respectively, of the glass panel 501 and the CCL frame 502 of the hybrid panel 500.

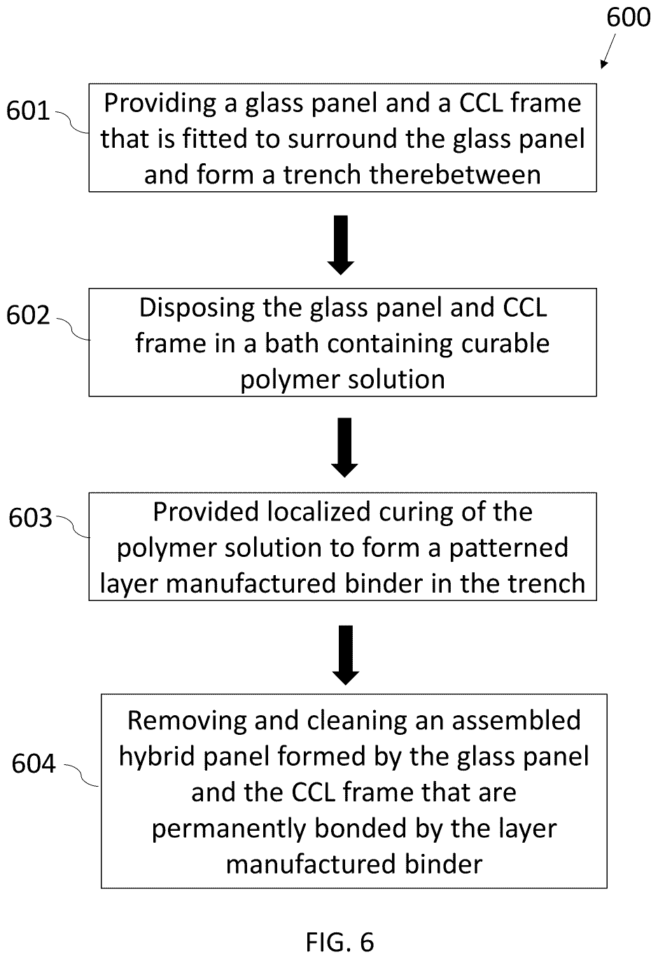

FIG. 6 shows a simplified flow diagram for an exemplary method 600 according to an aspect of the present disclosure.

The operation 601 may be directed to providing a glass panel and a CCL frame that is fitted to surround the glass panel and form a trench therebetween.

The operation 602 may be directed to disposing the glass panel and CCL frame in a bath containing a curable polymer solution.

The operation 603 may be directed to providing localized curing of the polymer solution to form a patterned layer manufactured binder in the trench.

The operation 604 may be directed to removing and cleaning an assembled hybrid panel formed by the glass panel and the CCL frame that are permanently bonded by the layer manufactured binder.

It will be understood that any property described herein for a particular hybrid semiconductor panel may also hold for any hybrid panel described herein. It will also be understood that any property described herein for a specific method for assembling such a hybrid panel may hold for any of the methods described herein. Furthermore, it will be understood that for any hybrid panel assembly and the methods described herein, not necessarily all the components or operations described will be shown in the accompanying drawings or method, but only some (not all) components or operations may be disclosed.

To more readily understand and put into practical effect the hybrid semiconductor panel assemblies having CCL frames, they will now be described by way of examples. For the sake of brevity, duplicate descriptions of features and properties may be omitted.

### EXAMPLES

Example 1 provides for a hybrid panel assembly including a glass panel, a copper clad laminate (CCL) configured as a CCL frame around the glass panel, for which a trench is formed between the glass panel and the CCL frame, and a layer manufactured binder, for which the layer manufactured binder is disposed in the trench between the glass panel and the CCL frame.

Example 2 may include the hybrid panel of example 1 and/or any other example disclosed herein, for which the layer manufactured binder is made of a cured resin that is formed layer-by-layer and is substantially void-free.

Example 3 may include the hybrid panel of example 2 and/or any other example disclosed herein, for which the layer manufactured binder is made of polyurethane acrylate.

Example 4 may include the hybrid panel of example 1 and/or any other example disclosed herein, for which the layer manufactured binder is made of a cured epoxy-based resin or acrylic-based resin accompanied by a filler material.

Example 5 may include the hybrid panel of example 1 and/or any other example disclosed herein, for which the layer manufactured binder has a thickness that is greater than a thickness of the glass panel.

Example 6 may include the hybrid panel of example 1 and/or any other example disclosed herein, for which the layer manufactured binder has a thickness that is co-planar with a thickness of the glass panel and a thickness of the CCL frame.

Example 7 may include the hybrid panel of example 1 and/or any other example disclosed herein, for which the glass panel has a size in a range of approximately 250×250 mm to 610×650 mm.

Example 8 may include the hybrid panel of example 2 and/or any other example disclosed herein, for which the glass panel and the CCL frame have a size of approximately 510×515 mm.

Example 9 provides for a method including forming a glass panel having outer peripheral edges, forming a CCL frame having inner peripheral edges, providing a bath containing a solution including a curable polymer, positioning the CCL frame and the glass panel in the bath, for which the outer peripheral edges of the glass panel are aligned with the inner peripheral edges of the CCL frame to form a trench between the CCL frame and the glass panel, and forming a layer manufactured binder in the trench by building layer-by-layer to bond the CCL frame and the glass panel to form an assembled hybrid panel, for which the layer manufactured binder is substantially void-free.

Example 10 may include the method of example 9 and/or any other example disclosed herein, for which forming the layer manufactured binder includes using a UV-curable polymer in the bath.

Example 11 may include the method of example 10 and/or any other example disclosed herein, for which forming the layer manufactured binder includes using a UV source to cure the UV-curable polymer in the bath.

Example 12 may include the method of example 11 and/or any other example disclosed herein, for which the UV source is coupled to a processor that is provided with a program to determine a polymerization pattern and rate.

Example 13 may include the method of example 9 and/or any other example disclosed herein, for which the positioning of the CCL frame further includes positioning the CCL frame on a support in the bath.

Example 14 may include the method of example 9 and/or any other example disclosed herein, for which the positioning of the glass panel further includes using a glass panel holder to pick up and position the glass panel.

Example 15 may include the method of example 9 and/or any other example disclosed herein, for which forming a layer manufactured binder in the trench uses a thermal curing process.

Example 16 may include the method of example 9 and/or any other example disclosed herein, which further includes removing the assembled hybrid panel from the bath and performing a cleaning process to remove any residual solution.

Example 17 provides for a hybrid panel assembly including a glass panel, a frame, for which the frame is configured to surround the glass panel, and a layer manufactured binder, for which the layer manufactured binder is disposed between and bonds the glass panel and the frame.

Example 18 may include the hybrid panel of example 17 and/or any other example disclosed herein, for which the layer manufactured binder is made of a cured resin that is formed layer-by-layer.

Example 19 may include the hybrid panel of example 17 and/or any other example disclosed herein, for which the layer manufactured binder is made of a cured resin and a filler material.

Example 20 may include the hybrid panel of example 17 and/or any other example disclosed herein, for which the frame is made of a copper clad laminate.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A hybrid panel assembly comprising:
a glass panel;
a copper clad laminate (CCL) configured as a CCL frame around the glass panel, wherein a trench is formed between the glass panel and the CCL frame; and
a layer manufactured binder, wherein the layer manufactured binder is disposed in the trench between the glass panel and the CCL frame.

2. The hybrid panel assembly of claim 1, wherein the layer manufactured binder is made of a cured resin that is formed layer-by-layer and is substantially void-free.

3. The hybrid panel assembly of claim 2, wherein the layer manufactured binder is made of polyurethane acrylate.

4. The hybrid panel assembly of claim 1, wherein the layer manufactured binder is made of a cured epoxy-based resin or acrylic-based resin accompanied by a filler material.

5. The hybrid panel assembly of claim 1, wherein the layer manufactured binder has a thickness that is greater than a thickness of the glass panel.

6. The hybrid panel assembly of claim 1, wherein the layer manufactured binder has a thickness that is co-planar with a thickness of the glass panel and a thickness of the CCL frame.

7. The hybrid panel assembly of claim 1, wherein the glass panel has a size in a range of approximately 250×250 mm to 610×650 mm.

8. The hybrid panel assembly of claim 2, wherein the glass panel and the CCL frame have a size of approximately 510×515 mm.

9. A method comprising:
forming a glass panel having outer peripheral edges;
forming a CCL frame having inner peripheral edges;
providing a bath containing a solution comprising a curable polymer;
positioning the CCL frame and the glass panel in the bath, wherein the outer peripheral edges of the glass panel are aligned with the inner peripheral edges of the CCL frame to form a trench between the CCL frame and the glass panel; and
forming a layer manufactured binder in the trench by building layer-by-layer to bond the CCL frame and the glass panel to form an assembled hybrid panel, wherein the layer manufactured binder is substantially void-free.

10. The method of claim 9, wherein forming the layer manufactured binder comprises using a UV-curable polymer in the bath.

11. The method of claim 10, wherein forming the layer manufactured binder comprises using a UV source to cure the UV-curable polymer in the bath.

12. The method of claim 11, wherein the UV source is coupled to a processor that is provided with a program to determine a polymerization pattern and rate.

13. The method of claim 9, wherein the positioning of the CCL frame further comprises positioning the CCL frame on a support in the bath.

14. The method of claim 9, wherein the positioning of the glass panel further comprises using a glass panel holder to pick up and position the glass panel.

15. The method of claim 9, wherein forming a layer manufactured binder in the trench uses a thermal curing process.

16. The method of claim 9, further comprises removing the assembled hybrid panel from the bath and performing a cleaning process to remove any residual solution.

17. A hybrid panel assembly comprising:
a glass panel;
a frame, wherein the frame is configured to surround the glass panel; and
a layer manufactured binder, wherein the layer manufactured binder is disposed between and bonds the glass panel and the frame.

18. The hybrid panel assembly of claim 17, wherein the layer manufactured binder is made of a cured resin that is formed layer-by-layer.

19. The hybrid panel assembly of claim 17, wherein the layer manufactured binder is made of a cured resin and a filler material.

20. The hybrid panel assembly of claim 17, wherein the frame is made of a copper clad laminate.
